(19) United States
(12) Patent Application Publication
(10) Pub. No.: US 2025/0124357 A1
(43) Pub. Date: Apr. 17, 2025

(54) INFORMATION PROCESSING METHOD, COMPUTER PROGRAM, AND INFORMATION PROCESSING APPARATUS

(71) Applicant: Tokyo Electron Limited, Tokyo (JP)

(72) Inventors: Joji TAKAYOSHI, Miyagi (JP); Kouichi YOSHIDA, Miyagi (JP); Chong SAI, Miyagi (JP); Takao FUNAKUBO, Miyagi (JP); Yuta KINOKUNI, Miyagi (JP)

(73) Assignee: Tokyo Electron Limited, Tokyo (JP)

(21) Appl. No.: 19/002,811

(22) Filed: Dec. 27, 2024

Related U.S. Application Data
(63) Continuation of application No. PCT/JP2023/024372, filed on Jun. 30, 2023.

(30) Foreign Application Priority Data
Jul. 4, 2022 (JP) 2022-107851

(51) Int. Cl. G06N 20/00

(52) U.S. Cl. CPC G06N 20/00

(57) ABSTRACT

An information processing method, a computer program, and an information processing apparatus. The information processing method includes acquiring operation data of a first semiconductor manufacturing apparatus provided with a plurality of sensors and sensor data output by the sensors when the first semiconductor manufacturing apparatus is operated, using machine learning to generate a learning model for outputting the sensor data in response to an input of the operation data based on the acquired operation data and the acquired sensor data, and disposing the generated learning model in a second semiconductor manufacturing apparatus different from the first semiconductor manufacturing apparatus.

### CROSS-REFERENCE TO RELATED APPLICATIONS

This application is a bypass continuation application of international application No. PCT/JP2023/024372 having an international filing date of Jun. 30, 2023 and designating the United States, the international application being based upon and claiming the benefit of priority from Japanese Patent Application No. 2022-107851, filed on Jul. 4, 2022, the entire contents of each are incorporated herein by reference.

### TECHNICAL FIELD

The present disclosure relates to an information processing method, a computer program, and an information processing apparatus.

### BACKGROUND

WO2014/050808 proposes an integrated management system that accumulates various information collected from substrate processing apparatuses and uses the accumulated data to display information required for energy conservation in each of the substrate processing apparatuses installed in a semiconductor manufacturing factory. The integrated management system accumulates various information including power consumption information, gas consumption information, or operation information of the substrate processing apparatus, acquires information satisfying a predetermined condition from the accumulated information, and calculates and displays at least one of a power consumption amount consumed by the substrate processing apparatus, inert gas consumption, and an apparatus operation rate of the substrate processing apparatus.

### CITATION LIST

### Patent Documents

Patent Literature 1: WO2014/050808

### SUMMARY

The present disclosure provides an information processing method, a computer program, and an information processing apparatus in which estimating an operation state or the like of a semiconductor manufacturing apparatus can be expected.

An information processing method according to an embodiment includes acquiring operation data of a first semiconductor manufacturing apparatus provided with a plurality of sensors and sensor data output by the sensors, when the first semiconductor manufacturing apparatus is operated, using machine learning to generate a learning model for outputting the sensor data in response to an input of the operation data, based on the acquired operation data and the acquired sensor data, and disposing the generated learning model in a second semiconductor manufacturing apparatus different from the first semiconductor manufacturing apparatus.

According to the present disclosure, estimating an operation state or the like of a semiconductor manufacturing apparatus can be expected.

### BRIEF DESCRIPTION OF DRAWINGS

FIG. 1 is a schematic diagram showing a configuration example of an information processing system according to the present embodiment.

FIG. 2 is a schematic diagram for describing an example of a sensor for a semiconductor manufacturing apparatus.

FIG. 3 is a block diagram showing a configuration example of the information processing apparatus according to the present embodiment.

FIG. 4 is a schematic diagram showing a configuration example of a process DB.

FIG. 5 is a flowchart showing an example of a procedure of a prediction model generation process performed by the information processing apparatus according to the present embodiment.

FIG. 6 is a schematic diagram showing an example of an information display relating to generation of a prediction model.

FIG. 7 is a schematic diagram showing an example of the information display relating to the generation of the prediction model.

FIG. 8 is a schematic diagram for describing a usage example in a simulation of the prediction model.

FIG. 9 is a flowchart showing an example of a procedure of a contribution degree calculation process performed by the information processing apparatus according to the present embodiment.

FIG. 10 is a schematic diagram showing an example of information display relating to a contribution degree.

FIG. 11 is a flowchart showing an example of a procedure of a unit stopping process performed by the information processing apparatus according to the present embodiment.

FIG. 12 is a schematic diagram for describing an advantageous effect of automatically stopping a unit in a standby state.

FIG. 13 is a schematic diagram showing a display example according to process timing verification.

FIG. 14 is a schematic diagram showing a display example according to the process timing verification.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### <System Configuration>

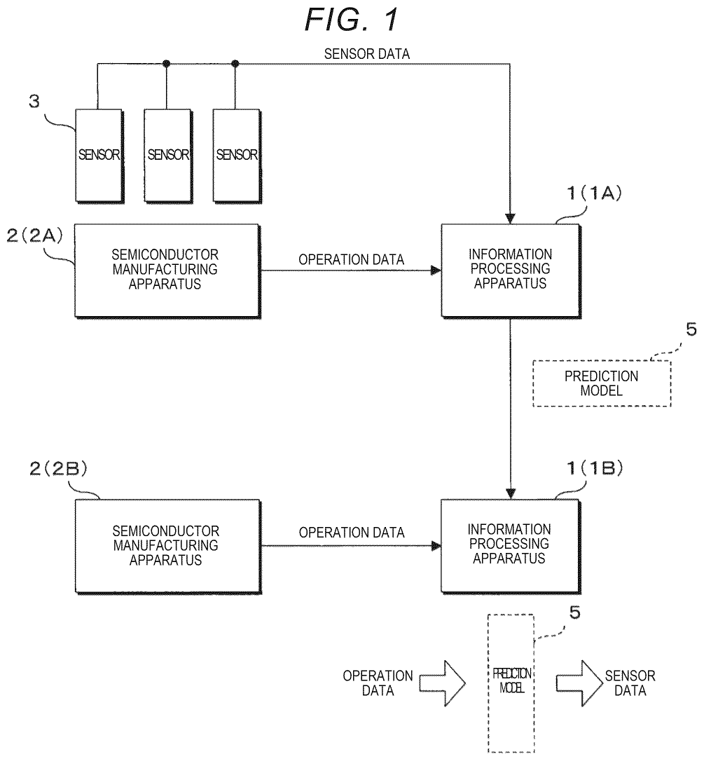

FIG. 1 is a schematic diagram showing a configuration example of an information processing system according to the present embodiment. The information processing system according to the present embodiment includes an information processing apparatus 1 and a semiconductor manufacturing apparatus 2. The semiconductor manufacturing apparatus 2 is an apparatus that performs various processing for semiconductor manufacturing such as chemical vapor deposition (CVD), sputtering, or etching. For example, the information processing apparatus 1 is an apparatus that acquires and collects operation data output by the semiconductor manufacturing apparatus 2, and monitors and controls an operation of the semiconductor manufacturing apparatus 2. There may be provided a plurality of the semiconductor manufacturing apparatuses 2, which are targets of the information processing apparatus 1 to be monitored, controlled, and the like. For example, operation data acquired by the information processing apparatus 1 may include various data such as process log data, recipe data, wafer transfer history data, and error data.

In the information processing system according to the present embodiment, a plurality of sensors 3 for measuring a detailed operation state or the like are provided for at least one semiconductor manufacturing apparatus 2, which is a target of the information processing apparatus 1 to be monitored, controlled, and the like. When the plurality of semiconductor manufacturing apparatuses 2 exist, the sensor 3 may be provided for some (at least one) of the plurality of semiconductor manufacturing apparatuses 2, instead of providing the sensors 3 for all of the semiconductor manufacturing apparatuses 2. In FIG. 1 and the following description, the semiconductor manufacturing apparatus 2 provided with the sensors 3 will be referred to as a semiconductor manufacturing apparatus 2A, and the semiconductor manufacturing apparatus 2 having no sensor 3 will be referred to as a semiconductor manufacturing apparatus 2B. When there is no need to distinguish the presence or absence of the sensors 3, the semiconductor manufacturing apparatuses 2A and 2B will be referred to simply as the semiconductor manufacturing apparatus 2. Similarly, the information processing apparatus 1 that performs monitoring, controlling, and the like of the semiconductor manufacturing apparatus 2A provided with the sensors 3 will be referred to as an information processing apparatus 1A, and an information processing apparatus 1 that performs monitoring, controlling, and the like of the semiconductor manufacturing apparatus 2B having no sensor 3 will be referred to as an information processing apparatus 1B. When there is no need to distinguish the information processing apparatuses 1A and 1B, the information processing apparatuses 1A and 1B will be simply referred to as the information processing apparatus 1.

In the present embodiment, the plurality of sensors 3 provided in the semiconductor manufacturing apparatus 2A are sensors that perform measurements relating to an environment, and, for example, include a sensor for measuring power consumption, a sensor for measuring a drainage amount, or a sensor for measuring a gas exhaust amount. For example, a gas whose exhaust amount is measured by the sensor may include a gas such as CO₂ (carbon dioxide) or NOx (nitrogen oxide). In the present embodiment, for example, the semiconductor manufacturing apparatus 2 is configured by combining various units such as an upper chiller, a radio frequency (RF) power source, a direct current (DC) power source, a vacuum pump, a chamber heater, an electric static chuck (ESC) heater, and a lower chiller. The plurality of sensors 3 may include sensors for measuring the power consumption, the drainage amount, the gas exhaust amount, or the like of each unit of the semiconductor manufacturing apparatus 2A.

In the information processing system according to the present embodiment, when a semiconductor manufacturing process is performed by the semiconductor manufacturing apparatus 2A provided with the sensors 3, the information processing apparatus 1A acquires operation data output by the semiconductor manufacturing apparatus 2A and sensor data as measurement results of the plurality of sensors 3, and stores and accumulates the acquired operation data and sensor data in association with each other in a database. The information processing apparatus 1A performs so-called a supervised machine learning process, based on the operation data and the sensor data which are accumulated in the database, and generates a learning model that receives an input of the operation data and outputs a prediction value of the sensor data as a prediction model 5. The information processing apparatus 1A deploys (disposes) the generated prediction model 5 in the information processing apparatus 1B of the semiconductor manufacturing apparatus 2B having no sensor 3. The information processing apparatus 1B can use the prediction model 5 generated by the information processing apparatus 1 to acquire a prediction value of the sensor data from the operation data output by the semiconductor manufacturing apparatus 2B, and can perform processing such as controlling or monitoring of the semiconductor manufacturing apparatus 2B based on the prediction value. In the present embodiment, disposing the prediction model 5 for the semiconductor manufacturing apparatus 2B or disposing the prediction model 5 for the information processing apparatus 1B of the semiconductor manufacturing apparatus 2B refers to a state where the prediction model 5 can predict the sensor data from the operation data of the semiconductor manufacturing apparatus 2B.

For example, in the information processing system according to the present embodiment, the semiconductor manufacturing apparatus 2A is installed at a base of an enterprise or the like which develops, sells, or the like the semiconductor manufacturing apparatus 2, for example. A test operation is performed on the semiconductor manufacturing apparatus 2A, and in this case, various measurements for the power consumption, the drainage amount, and the gas exhaust amount are performed by the sensors 3, and the sensor data output by the sensor 3 is accumulated together with operation data. After the operation data and the sensor data are sufficiently accumulated, the prediction model 5 is generated by the information processing apparatus 1A.

Thereafter, in the information processing system according to the present embodiment, for example, when one or more semiconductor manufacturing apparatuses 2B are installed at one or more bases, no sensor 3 is provided for each semiconductor manufacturing apparatus 2B (or a smaller number of the sensors 3 than the number of the sensors 3 provided for the semiconductor manufacturing apparatus 2A may be provided). Instead of providing the sensor 3 for each semiconductor manufacturing apparatus 2B, the prediction model 5 generated by the information processing apparatus 1A is installed in (introduced into) the information processing apparatus 1B for performing monitoring, controlling, or the like on each semiconductor manufacturing apparatus 2B, and the prediction model 5 is deployed (disposed) for each semiconductor manufacturing apparatus 2B. For example, the information processing apparatus 1B can acquire sensor data output by the prediction model 5 without using the sensors 3 by acquiring the operation data along with an initial operation of the semiconductor manufacturing apparatus 2B and inputting the acquired operation data to the prediction model 5.

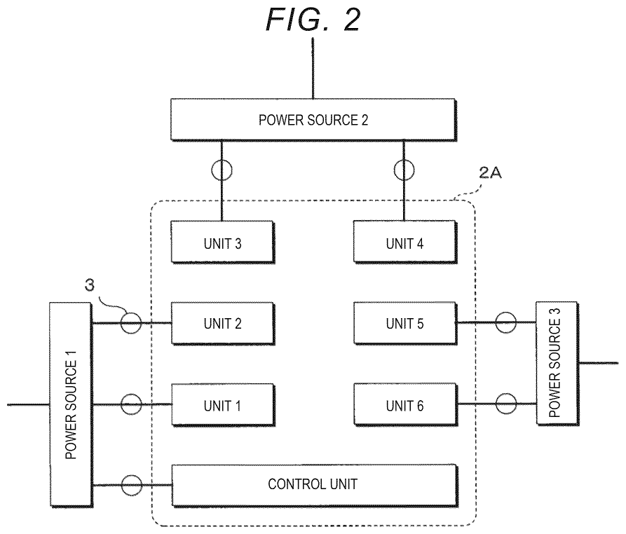

FIG. 2 is a schematic diagram for describing an example of the sensor 3 for the semiconductor manufacturing apparatus 2A. The semiconductor manufacturing apparatus 2A shown in FIG. 2 includes six units 1 to 6, and a control unit that controls the units. Power is supplied from three power sources 1 to 3 to the semiconductor manufacturing apparatus 2A. The power source 1 supplies the power to the control unit, the unit 1, and the unit 2. The power source 2 supplies the power to the unit 3 and the unit 4. The power source 3 supplies the power to the unit 5 and the unit 6. For example, the power sources 1 to 3 each supply the power from a commercial AC power source to each unit of the semiconductor manufacturing apparatus 2A.

In FIG. 2, individual power supply paths from the power sources to each of the units are indicated by thick solid lines. In the information processing system according to the present embodiment, for example, each sensor for measuring the power consumption is provided for each of the power supply paths. A circle overlapping the thick solid line in FIG. 2 is a position where the sensor 3 is provided. In the present example, seven power supply paths exist from the three power sources 1 to 3 to the seven units, and seven sensors 3 are provided. In this way, many sensors 3 are needed to measure the power consumption of each unit of the semiconductor manufacturing apparatus 2. However, for example, when many semiconductor manufacturing apparatuses 2 are installed in a semiconductor manufacturing factory and the sensors 3 are provided for all of the semiconductor manufacturing apparatuses 2, there is a possibility of a cost increase. Therefore, in the information processing system according to the present embodiment, the operation data and the sensor data are acquired by using the semiconductor manufacturing apparatus 2A provided with the sensors 3 in a test operation stage, and the prediction model 5 is generated, based on the acquired data. In an actual operation stage, the sensor 3 is not provided in the semiconductor manufacturing apparatus 2B (or a smaller number of the sensors 3 may be provided, compared to the test operation stage), and the sensor data is acquired by using the prediction model 5 instead of using the sensor 3.

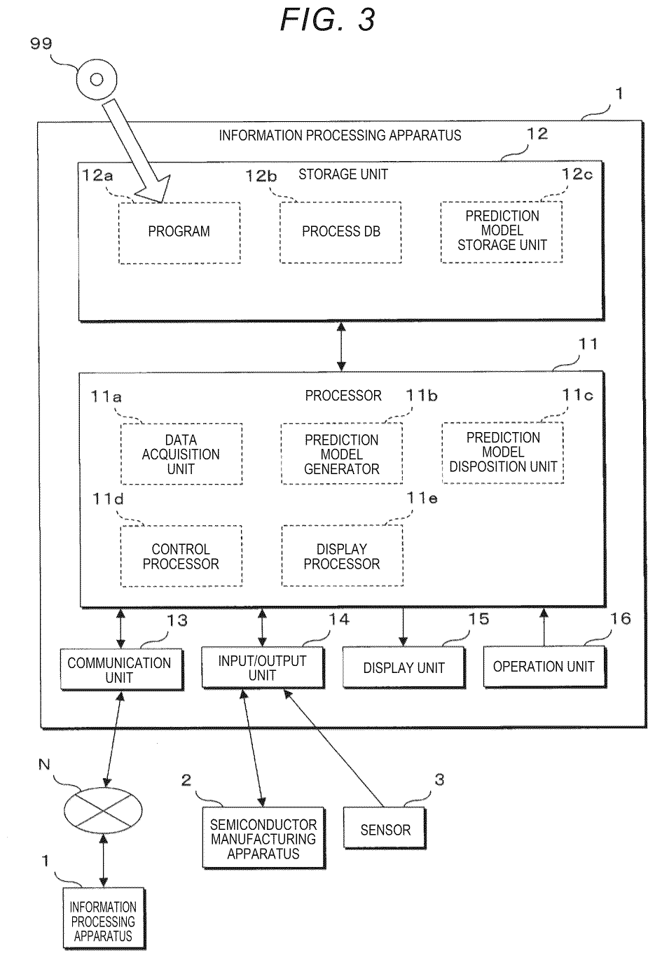

FIG. 3 is a block diagram showing a configuration example of the information processing apparatus 1 according to the present embodiment. The information processing apparatus 1 according to the present embodiment includes a processor 11, a storage unit (storage) 12, a communication unit (transceiver) 13, an input/output unit 14, a display unit 15, an operation unit 16, and the like. In the present embodiment, an example will be described in which a process is performed by one information processing apparatus 1. Meanwhile, the process of the information processing apparatus 1 may be distributed and performed by a plurality of apparatuses.

The processor 11 is configured by using an arithmetic processing apparatus such as a central processing unit (CPU), a micro-processing unit (MPU), a graphics processing unit (GPU), or a quantum processor, a read only memory (ROM), a random access memory (RAM), and the like. The processor 11 reads and executes a program 12a stored in the storage unit 12, thereby performing various processing such as processing for acquiring the operation data of the semiconductor manufacturing apparatus 2, processing for acquiring the sensor data measured by the sensors 3, and processing for generating the prediction model 5 based on these data.

The storage 12 is configured by using, for example, a large-capacity storage apparatus such as a hard disk. The storage 12 stores various types of programs to be executed by the processor 11 and various types of data necessary for the process of the processor 11. In the present embodiment, the storage 12 stores the program 12a to be executed by the processor 11. The storage unit 12 is provided with a process DB (database) 12b for storing the operation data acquired from the semiconductor manufacturing apparatus 2 and the sensor data acquired from the sensors 3 in association with each other, and a prediction model storage unit 12c for storing information relating to the prediction model 5 generated by using machine learning based on these data.

In the present embodiment, the program (computer program, program product) 12a is provided in a form recorded on a recording medium 99 such as a memory card or an optical disc. The information processing apparatus 1 reads the program 12a from the recording medium 99, and stores the program 12a in the storage unit 12. However, for example, the program 12a may be written into the storage unit 12 during a manufacturing stage of the information processing apparatus 1. For example, as the program 12a, the information processing apparatus 1 may acquire those which are distributed by a remote server device or the like through communication. For example, the program 12a may be written into the storage unit 12 of the information processing apparatus 1 after a writing apparatus reads data recorded in the recording medium 99. The program 12a may be provided in the form of distribution through a network, or may be provided in the form recorded in the recording medium 99.

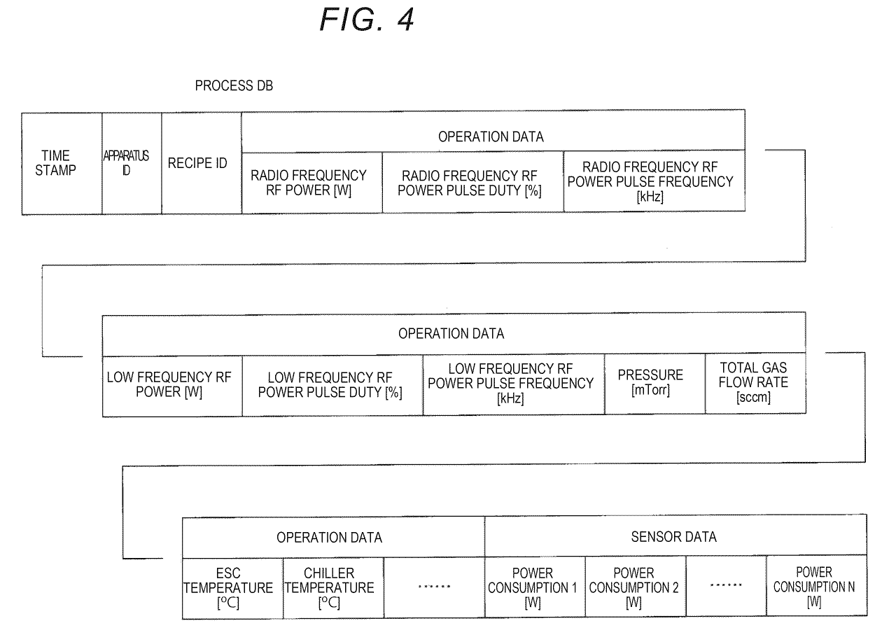

The process DB 12b is a database in which the information processing apparatus 1A stores the operation data acquired from the semiconductor manufacturing apparatus 2A and the sensor data acquired from the sensors 3 in association with each other. FIG. 4 is a schematic diagram showing a configuration example of the process DB 12b. For example, the shown process DB 12b stores data such as a “time stamp”, an “apparatus ID”, a “recipe ID”, the “operation data”, and the “sensor data” in association with each other. For example, the “time stamp” is information on the date and time when the information processing apparatus 1A acquires the operation data and the sensor data. The “apparatus ID” is identification information uniquely assigned to the semiconductor manufacturing apparatus 2, and for example, may be determined in advance by a designer or administrator of the information processing system according to the present embodiment. The “recipe ID” is information such as procedures or settings of a semiconductor manufacturing process performed by the semiconductor manufacturing apparatus 2, that is, identification information uniquely assigned to a so-called recipe, and for example, may be determined in advance by a user such as an administrator of the information processing system or a worker who carries out work for manufacturing the semiconductor.

For example, the “operation data” may include various types of information such as “radio frequency RF power [W]”, “radio frequency RF power pulse duty [%]”, “radio frequency RF power pulse frequency [kHz]”, “low frequency RF power [W]”, “low frequency RF power pulse duty [%]”, “low frequency RF power pulse frequency [kHz]”, “pressure [mTorr]”, “total gas flow rate [sccm]”, “ESC temperature [° C.]]”, and “chiller temperature [° C.]”. The information included in the operation data shown as an example in this drawing is information included in so-called process log data output as the semiconductor manufacturing apparatus 2 performs the semiconductor manufacturing process. The information included in the operation data is not limited to the information of the process log data, and may include various types of information such as recipe data, wafer transfer history data, and error data. The recipe data is obtained by collecting information such as procedures or settings of the semiconductor manufacturing process. For example, the wafer transfer history data is obtained by collecting information relating to wafer transfer such as an ID of a transferred wafer and the date and time when the transfer is performed. For example, the error data is obtained by collecting information such as the date and time when an error (abnormality, malfunction, or the like) is detected in the semiconductor manufacturing apparatus 2, and a type of the error.

For example, the “sensor data” may include information such as “power consumption 1[W]”, “power consumption 2[W]”, . . . “power consumption N[W]”. The sensor data shown as an example in this drawing is based on an assumption that the sensors 3 individually measure power consumption of the N-number of units provided in the semiconductor manufacturing apparatus 2. The information included in the sensor data is not limited to the power consumption, and for example, may include various types of information that can be detected by the sensor 3, such as the drainage amount or the gas exhaust amount. The information included in the sensor data does not need to be information of each unit of the semiconductor manufacturing apparatus 2.

For example, the information processing apparatus 1A repeatedly acquires the operation data while the semiconductor manufacturing apparatus 2A performs the semiconductor manufacturing process, and stores the acquired operation data in the process DB 12b. Accordingly, time series operation data is accumulated in the process DB 12b, and for example, a plurality of types of operation data are accumulated in the process DB 12b by performing the semiconductor manufacturing process on a single wafer. The information processing apparatus 1B that performs monitoring, controlling, or the like on the semiconductor manufacturing apparatus 2B having no sensor 3 does not need to have the process DB 12b. However, in the present embodiment, the information processing apparatus 1B also includes the process DB 12b, and stores data other than the sensor data, for example, the “time stamp”, the “apparatus ID”, the “recipe ID”, and the “operation data”.

The prediction model storage unit 12c of the storage unit 12 stores information relating to the prediction model 5 generated by the information processing apparatus 1A, based on the operation data and the sensor data which are stored in the process DB 12b. For example, the information relating to the prediction model 5 may include configuration information indicating that the prediction model 5 has any configuration, and information such as values of parameters inside the prediction model 5. In a case of the information processing apparatus 1A that performs monitoring, controlling, or the like on the semiconductor manufacturing apparatus 2A provided with the sensors 3, the prediction model storage unit 12c stores information relating to the prediction model 5 generated by itself. In a case of the information processing apparatus 1B that performs monitoring, controlling, or the like on the semiconductor manufacturing apparatus 2B having no sensor 3, the prediction model storage unit 12c stores information relating to the prediction model 5 generated by the other information processing apparatus 1A.

The communication unit 13 of the information processing apparatus 1 communicates with various apparatuses via a wired or wireless network N including a local area network (LAN), the Internet, a cellular phone communication network, or the like. The communication unit 13 transmits data supplied from the processor 11 to another apparatus, and supplies data received from another apparatus to the processor 11. In the present embodiment, the communication unit 13 communicates with the other information processing apparatuses 1 via the network N to exchange information relating to the prediction model 5.

The input/output unit 14 is connected to the semiconductor manufacturing apparatus 2 via a communication line, a signal line, or the like, and exchanges information with the semiconductor manufacturing apparatus 2. In the present embodiment, the input/output unit 14 receives an input of the operation data output by the semiconductor manufacturing apparatus 2, acquires the operation data, and supplies the operation data to the processor 11. The input/output unit 14 outputs a control command or the like supplied from the processor 11 to the semiconductor manufacturing apparatus 2. In the information processing apparatus 1A that performs monitoring, controlling, or the like on the semiconductor manufacturing apparatus 2A provided with the sensors 3, the input/output unit 14 is connected to one or more sensors 3. The input/output unit 14 receives an input of the sensor data output by the sensor 3, acquires the sensor data, and supplies the sensor data to the processor 11.

In the present embodiment, a configuration is adopted in which the information processing apparatus 1A directly acquires the sensor data of the sensors 3. However, the present disclosure is not limited to this configuration. A configuration may be adopted in which the semiconductor manufacturing apparatus 2A acquires the sensor data output by the sensors 3, and the semiconductor manufacturing apparatus 2A transmits the operation data and the sensor data to the information processing apparatus 1A.

The display unit 15 is configured by using a liquid crystal display or the like, and displays various images, characters, and the like, based on processing in the processor 11. For example, the display unit 15 displays various types of information such as the operation data acquired from the semiconductor manufacturing apparatus 2, the sensor data acquired from the sensors 3, and information relating to the prediction model generated from these data.

The operation unit 16 receives a user's operation, and notifies the processor 11 of the received operation. For example, the operation unit 16 receives the user's operation by an input device such as a mechanical button or a touch panel provided on a surface of the display unit 15. For example, the operation unit 16 may be an input device such as a mouse and a keyboard, and these input devices may be configured to be detachable from the information processing apparatus 1.

The storage unit 12 may be an external storage device connected to the information processing apparatus 1. The information processing apparatus 1 may be a multi-computer including a plurality of computers, or may be a virtual machine virtually constructed by software. The information processing apparatus 1 is not limited to the configuration described above, and does not need to include the display unit 15, the operation unit 16, and the like, for example.

In the information processing apparatus 1 of the present embodiment, the processor 11 reads and executes the program 12a stored in the storage unit 12. In this manner, a data acquisition unit 11a, a prediction model generator 11b, a prediction model disposition unit 11c, a control processor 11d, a display processor 11e, and the like are implemented as software-like functional units in the processor 11. The information processing apparatus 1B that performs monitoring, controlling, or the like on the semiconductor manufacturing apparatus 2B having no sensor 3 does not need to have the data acquisition unit 11a, the prediction model generator 11b, and the prediction model disposition unit 11c.

The data acquisition unit 11a performs processing for acquiring the operation data output by the semiconductor manufacturing apparatus 2A, for example, while or after the semiconductor manufacturing apparatus 2A performs the semiconductor manufacturing process. The data acquisition unit 11a performs processing for acquiring the sensor data output by one or more sensors 3, for example, at a timing the same as a timing at which the operation data is acquired from the semiconductor manufacturing apparatus 2A. The data acquisition unit 11a adds information such as the “time stamp”, the “apparatus ID”, and the “recipe ID” to the acquired operation data and sensor data, and stores the information in the process DB 12b in association with each other.

The prediction model generator 11b performs a process of generating the prediction model 5 by performing a process of machine learning using the operation data and the sensor data which are acquired by the data acquisition unit 11a and accumulated in the process DB 12b. In the present embodiment, the prediction model 5 is a learning model that receives an input of the operation data and outputs a prediction value of the sensor data. The prediction model generator 11b uses the operation data stored in the process DB 12b as input data (explanatory variable), generates training data (so-called labeled data) associated with the sensor data corresponding to the operation data as a correct value (response variable), and generates the prediction model 5 by performing the process of the machine learning (so-called supervised learning) using the training data. The prediction model generator 11b stores the generated information relating to the prediction model 5 in the prediction model storage unit 12c. The prediction model generator 11b may repeat generation (updating) of the prediction model 5 in a predetermined cycle such as once a week or once a month, for example.

In the present embodiment, for example, a partial least squares (PLS) regression model may be adopted as the prediction model 5. Meanwhile, various learning models such as an Auto-Regressive with eXogenous (ARX) model, a Support Vector Machine (SVM), a random forest, or a neural network may be adopted as the prediction model 5. For example, the prediction model 5 may be configured to receive an input of time series operation data and output time series sensor data. In this case, for example, a learning model such as a Recurrent Neural Network (RNN), a Long Short Term Memory (LSTM), or a Transformer may be adopted as the prediction model 5. Since a structure of the learning model and a method for generating the learning model through the machine learning are existing techniques, detailed description thereof will be omitted in the present embodiment.

The prediction model disposition unit 11c performs processing for disposing (deploying) the prediction model 5 generated by the prediction model generator 11b for the information processing apparatus 1B that performs monitoring, control, and the like on the semiconductor manufacturing apparatus 2B having no sensor 3. For example, the prediction model disposition unit 11c can dispose the prediction model 5 in the information processing apparatus 1B by receiving information input such as the apparatus ID of the information processing apparatus 1B which is a disposition destination from the user, reading information relating to the prediction model 5 from the prediction model storage unit 12c, and transmitting the information relating to the prediction model 5 to the information processing apparatus 1B which is the disposition destination receiving the input. The information processing apparatus 1B receiving the information relating to the prediction model 5 from the information processing apparatus 1A can store the received information in the prediction model storage unit 12c of the storage unit 12 belonging to itself, and can use the prediction model 5 in subsequent processing. When the prediction model generator 11b repeatedly generates (updates) the prediction model 5, each time the prediction model 5 is updated, the prediction model disposition unit 11c may transmit (re-dispose) information relating to the updated prediction model 5 to the information processing apparatus 1B in which the prediction model 5 is previously disposed.

The control processor 11d performs control processing of the semiconductor manufacturing apparatus 2, based on the operation data acquired from the semiconductor manufacturing apparatus 2 and the sensor data acquired from the sensor 3 or predicted by the prediction model 5. For example, the control processor 11d monitors a change in the power consumption (power consumption amount) of each unit of the semiconductor manufacturing apparatus 2 based on the sensor data, determines an operation state of each unit based on the power consumption, and stops an operation (stops power supply) of the unit in a standby state (state where no processing is performed). In this manner, the control processor 11d can perform controlling to reduce the power consumption in the whole semiconductor manufacturing apparatus 2. For example, the control processor 11d can determine the presence or absence of an abnormality in each unit based on the operation data or the sensor data, and can perform controlling to stop the operation of the unit or the semiconductor manufacturing apparatus 2 when it is determined that the abnormality is present. The control processing of the semiconductor manufacturing apparatus 2 which is performed by the control processor 11d may be any processing.

The display processor 11e performs processing for displaying various types of information on the display unit 15. For example, the display processor 11e can graphically display a time-dependent change in various information included in the operation data and the sensor data which are acquired by the data acquisition unit 11a. For example, the display processor 11e can display various types of information such as information relating to the prediction model 5 generated by the prediction model generator 11b, for example, comparison information between measurement values measured by the sensors 3 and prediction values obtained by the prediction model 5, and prediction accuracy obtained by the prediction model 5. For example, the display processor 11e can cause the display unit 15 to display prediction values such as the power consumption, the drainage amount, and the gas exhaust amount of the semiconductor manufacturing apparatus 2 based on the sensor data output by the prediction model 5 based on the operation data acquired by the data acquisition unit 11a. In this case, for example, the display processor 11e may convert the power consumption into information such as an exhaust amount of carbon dioxide and may display the converted information by performing a predetermined calculation on the prediction value of the power consumption of the semiconductor manufacturing apparatus 2.

### <Prediction Model Generation Process>

In the information processing system according to the present embodiment, for example, a user such as a designer or an administrator of the present system appropriately selects one or more semiconductor manufacturing apparatuses 2A from the plurality of semiconductor manufacturing apparatuses 2, and the sensor 3 is provided in the selected semiconductor manufacturing apparatus 2A. The user performs the semiconductor manufacturing process in the semiconductor manufacturing apparatus 2A. In this case, the information processing apparatus 1A acquires the operation data of the semiconductor manufacturing apparatus 2A and the sensor data of the sensors 3 and stores and accumulates the data in the process DB 12b. After sufficient data is accumulated in the process DB 12b, the information processing apparatus 1A generates the prediction model 5 by performing the machine learning using the accumulated operation data and sensor data, for example in accordance with a user's operation or repeating in a predetermined cycle. The information processing apparatus 1A transmits the information relating to the generated prediction model 5 to the information processing apparatus 1B. In this manner, the information processing apparatus 1A is brought into a state where the prediction model 5 can be used for performing monitoring, controlling, or the like on the semiconductor manufacturing apparatus 2B having no sensor 3.

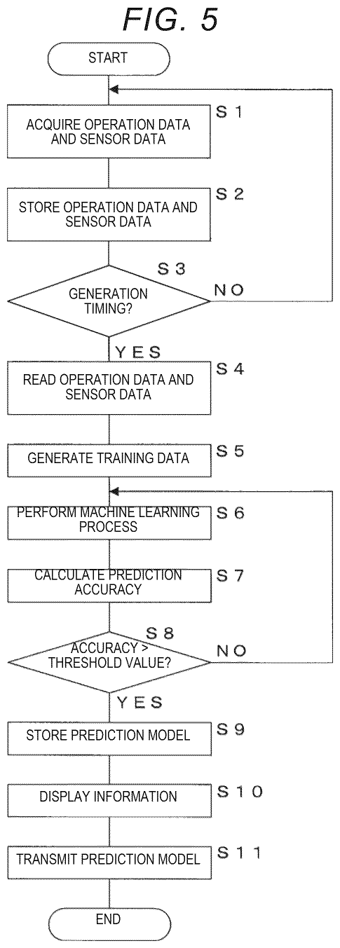

FIG. 5 is a flowchart showing an example of a procedure of the prediction model generation process performed by the information processing apparatus 1A according to the present embodiment. The data acquisition unit 11a of the processor 11 of the information processing apparatus 1A according to the present embodiment acquires the operation data output by the semiconductor manufacturing apparatus 2A and the sensor data output by the sensor 3 in a predetermined cycle when the semiconductor manufacturing process of the semiconductor manufacturing apparatus 2A is performed (Step S1). The data acquisition unit 11a stores the operation data and the sensor data which are acquired in Step S1 in the process DB 12b of the storage unit 12 (Step S2).

The processor 11 determines whether it is a timing for generating the prediction model 5 (Step S3). In this case, the processor 11 can determine that it is the timing for generating the prediction model 5, for example, when it is a timing for updating the prediction model 5 at which the processing is repeatedly performed in a predetermined cycle, when an instruction for generating the prediction model 5 is received from the user, or when a predetermined amount of the operation data and the sensor data are accumulated in the process DB 12b. When it is not the timing for generating the prediction model 5 (S3: NO), the processor 11 returns the process to Step S1, and continuously collects the data in Steps S1 and S2.

When it is the timing for generating the prediction model 5 (S3: YES), the prediction model generator 11b of the processor 11 reads the operation data and the sensor data which are stored in the process DB 12b (Step S4). The prediction model generator 11b receives an input (explanatory variable) of the operation data read in Step S4 and generates training data associated with the sensor data as a correct value (response variable) (Step S5). In this case, the prediction model generator 11b may appropriately perform processing such as normalization or regularization of numerical values included in the operation data and the sensor data. The prediction model generator 11b uses the training data generated in Step S5, performs supervised machine learning processing on the learning model having a predetermined configuration (Step S6), and generates the prediction model 5 by determining internal parameters of the learning model.

The prediction model generator 11b calculates prediction accuracy by performing prediction using verification data generated separately from the training data on the prediction model 5 generated in Step S6 (Step S7). The verification data is data having the same format as the training data. For example, some of all data stored in the process DB 12b may be used as the verification data, and the rest may be used as the training data. The prediction model generator 11b determines whether the prediction accuracy calculated in Step S7 exceeds a threshold value (Step S8). The threshold value is the prediction accuracy required for the prediction model 5 and is determined in advance by a user such as a designer or an administrator of the present system, for example. When the prediction accuracy does not exceed the threshold value (S8: NO), the prediction model generator 11b returns the process to Step S6 and repeats the machine learning process to improve the prediction accuracy.

When the prediction accuracy exceeds the threshold value (S8: YES), the prediction model generator 11b stores the information relating to the generated prediction model in the prediction model storage unit 12c of the storage unit 12 (Step S9). For example, the display processor 11e of the processor 11 displays information such as prediction accuracy of the generated prediction model 5 on the display unit 15 (Step S10). The prediction model disposition unit 11c of the processor 11 transmits the information relating to the generated prediction model 5 to the information processing apparatus 1B that performs monitoring, control, or the like of the semiconductor manufacturing apparatus 2B having no sensor 3 (Step S11). In this manner, the prediction model 5 is disposed for the semiconductor manufacturing apparatus 2B, and the processing is completed.

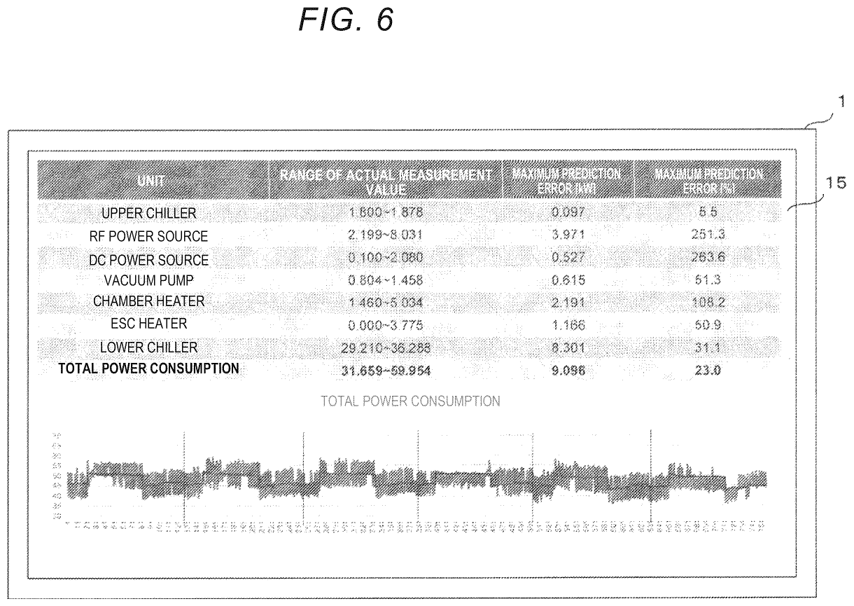

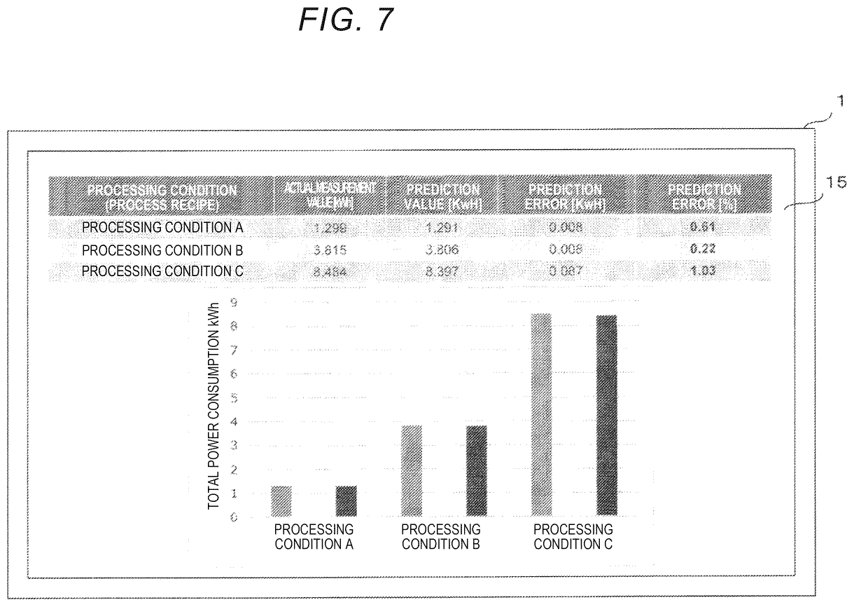

FIGS. 6 and 7 are schematic diagrams showing an example of information display relating to the generation of the prediction model 5. For example, these drawings are examples of information displayed in Step S10 of a flowchart in FIG. 5. In the information display example shown in FIG. 6, the information processing apparatus 1A displays a table showing a prediction error of the power consumption of each unit of the semiconductor manufacturing apparatus 2A and a graph showing a time-dependent change in an actual measurement value and a prediction value of total power consumption in such a manner that the table and the graph are aligned up and down on a screen of the display unit 15. In the table showing the prediction error, for example, a name of the unit of the semiconductor manufacturing apparatus 2A, a range of the actual measurement value of the power consumption, a value [KW] of a maximum prediction error, and a ratio [%] are shown in association with each other. In the graph of the total power consumption, a horizontal axis represents a time, a vertical axis represents the power consumption, the actual measurement value of the total power consumption is indicated by a light-gray polygonal line, and the prediction value is indicated by a dark-gray polygonal line. In this graph, it can be understood that the actual measurement values oscillate up and down, and the prediction value indicates a value close to a median value or an average value of the actual measurement values.

The information processing apparatus 1A can calculate a prediction error or the like shown in the drawing by performing verification using the verification data prepared in advance for the generated prediction model 5. The verification data is data having the same configuration as the training data, generated using the operation data and the sensor data which are stored in the process DB 12b. The information processing apparatus 1A inputs the operation data included in the verification data to the prediction model 5, and acquires a prediction value of the sensor data output by the prediction model 5. The information processing apparatus 1A can calculate the prediction error by calculating a difference between the actual measurement value of the sensor data included in the verification data and the prediction value of the sensor data obtained by the prediction model 5.

In addition, in the information display example shown in FIG. 7, the information processing apparatus 1A displays information for comparing the total power consumption consumed in each process, for each processing condition (process recipe) when the semiconductor manufacturing process is performed in the semiconductor manufacturing apparatus 2A. The information processing apparatus 1A displays a table showing the prediction error for each processing condition and a bar graph showing the total power consumption for each processing condition in such a manner that the table and the bar graph are aligned up and down on the screen of the display unit 15. For example, with regard to three processing conditions A to C, an actual measurement value [kWh] and a prediction value [kWh] of the total power consumption, and a value [kWh] and a ratio [%] of the prediction error are association with each other and indicated in the table showing the prediction error for each processing condition. In the bar graph of the total power consumption, for example, with regard to the three processing conditions A to C, the actual measurement value of the total power consumption is indicated in a light gray color, and the prediction value is indicated in a dark gray color.

### <Usage of Prediction Model 5>

In the information processing system according to the present embodiment, the prediction model 5 generated by the information processing apparatus 1A can be used for various types of processing. Hereinafter, some usage examples of the prediction model 5 will be described.

### (1) Usage in Simulation

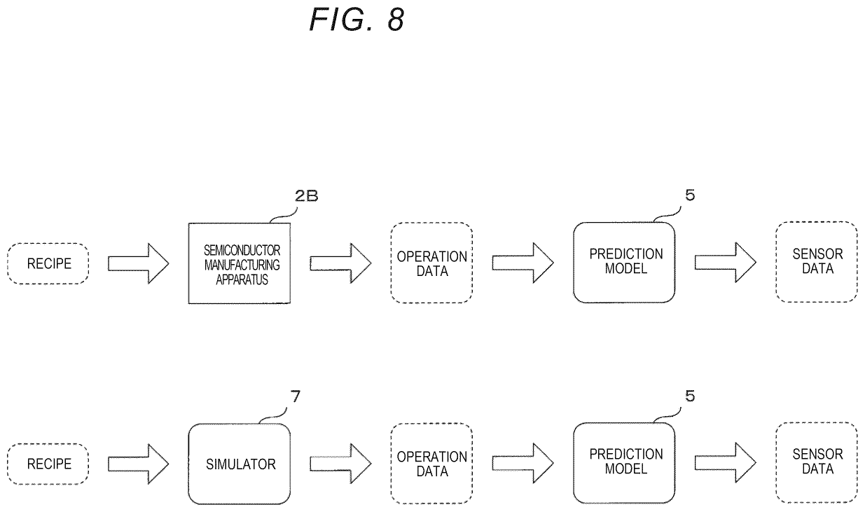

FIG. 8 is a schematic diagram for describing a usage example of the prediction model 5 in a simulation. An upper stage in FIG. 8 shows a flow when the prediction model 5 predicts the sensor data, based on the operation data output by the semiconductor manufacturing apparatus 2. For example, a user such as a designer or an administrator of the present system prepares recipe data of the semiconductor manufacturing process and inputs the recipe data to the semiconductor manufacturing apparatus 2B. The semiconductor manufacturing apparatus 2B performs the semiconductor manufacturing process based on the input recipe data and outputs the operation data such as process log data. The information processing apparatus 1B inputs the operation data acquired from the semiconductor manufacturing apparatus 2B to the prediction model 5 generated in advance and acquires the prediction value of the sensor data output by the prediction model 5.

A lower stage in FIG. 8 shows a flow when the prediction model 5 is used in a simulator 7 of the semiconductor manufacturing apparatus 2. The simulator 7 is software for simulating the semiconductor manufacturing process performed by the semiconductor manufacturing apparatus 2. For example, the simulator 7 receives an input of the recipe data including information such as settings of the semiconductor manufacturing process performed by the semiconductor manufacturing apparatus 2, simulates the process performed by the semiconductor manufacturing apparatus 2 in accordance with the recipe data, and generates the operation data output by the semiconductor manufacturing apparatus 2 as a result of the simulation. For example, the user inputs the recipe data prepared by the user himself/herself to the simulator 7, performs the simulation, and inputs the operation data output by the simulator 7 to the prediction model 5. In this manner, the prediction value of the sensor data output by the prediction model 5 can be acquired. Based on the sensor data output by the prediction model 5, the user can verify the power consumption amount, the drainage amount, the gas exhaust amount, or the like of the semiconductor manufacturing apparatus 2 when the processing is performed based on the recipe data prepared by the user himself/herself. For example, the user can repeatedly perform the simulation while correcting the recipe data to improve the power consumption amount, the drainage amount, or the gas exhaust amount.

In this way, since the prediction model 5 generated by the information processing apparatus 1A is used for the simulation, the user can verify the power consumption amount, the drainage amount, the gas exhaust amount, or the like of the semiconductor manufacturing apparatus 2 under various conditions, without actually operating the semiconductor manufacturing apparatus 2A. In FIG. 8, the simulator 7 and the prediction model 5 are shown as separate blocks. However, the prediction model 5 may be incorporated and used in the simulator 7. In this case, the simulator 7 can output the prediction value of the sensor data together with the operation data. In addition, the processing such as the simulation performed by the simulator 7 and the acquisition of the prediction value of the sensor data by using the prediction model 5 may be performed by an apparatus different from the information processing apparatus 1 that performs monitoring, control, or the like of the semiconductor manufacturing apparatus 2, for example, an information processing apparatus for a simulation purpose.

### (2) Verification of Contribution Degree

For example, the learning model generated by using the machine learning can calculate contribution degree (importance degree, influence degree, or the like) of input data (explanatory variable) to output data (response variable) by using explainable Artificial Intelligence (XAI) techniques such as SHapley Additive explanations (SHAP) or Local Interpretable Model-agnostic Explanations (LIME). In the information processing system according to the present embodiment, the information processing apparatus 1 can calculate the contribution degree to the sensor data output by the prediction model 5 with regard to various items included in the operation data input to the prediction model 5, can display a calculation result on the display unit 15, and can present the calculation result to the user. The information processing apparatus 1 may display information relating to the contribution degree, for example, based on a user's operation, or may display the information, for example, when an abnormality or the like is detected in the sensor data output by the prediction model 5.

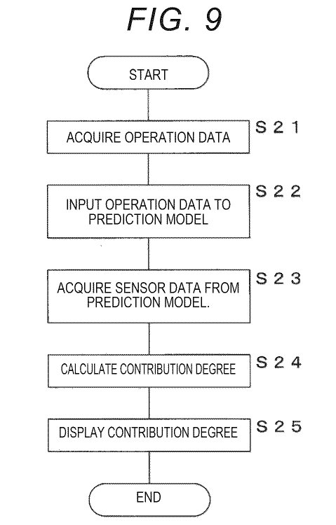

FIG. 9 is a flowchart showing an example of a procedure of a contribution degree calculation process performed by the information processing apparatus 1 according to the present embodiment. The processor 11 of the information processing apparatus 1 according to the present embodiment receives designation of a range or the like of the operation data, for example, which is a verification target of the contribution degree from the operation data stored in the process DB 12b, from the user, and acquires the target operation data (Step S21). The processor 11 inputs the operation data acquired in Step S21 to the trained prediction model 5 in which information such as a structure and parameters is stored in the prediction model storage unit 12c (Step S22). The processor 11 acquires the sensor data output by the prediction model 5 with respect to the operation data input in Step S22 (Step S23).

The processor 11 calculates the contribution degree of each item included in the operation data input to the prediction model 5 (Step S24). In this case, for example, the processor 11 can calculate the SHAP value (Sharpley value) of each item included in the operation data, and can set those obtained by calculating the average value, the total value, or the like of the SHAP values of each item as the contribution degree of each item of the operation data. The SHAP value is a numerical value that indicates how much the output data is affected by each item of the input data with respect to the learning model. Since the calculation of the SHAP value is an existing technique, detailed description of the calculation method will be omitted. The processor 11 displays the contribution degree calculated in Step S24 on the display unit 15 (Step S25) and completes the process.

In the present example, the contribution degree of each item of the operation data is calculated by using the SHAP value. Meanwhile, as the method for calculating the contribution degree, a method other than using the SHAP value may be adopted. For example, when the learning model such as a Recurrent Neural Network (RNN), a Long Short Term Memory (LSTM), or a Transformer is adopted as the prediction model 5, the contribution degree may be calculated by using an attention mechanism. For example, when the learning model having a tree structure such as a decision tree, a random forest, eXtreme Gradient Boosting (XGBoost), or Light Gradient Boosting Machine (LightGBM) is adopted as the prediction model 5, the contribution degree may be calculated based on the structure of the generated learning model.

When the PLS regression model is adopted as the prediction model 5, for example, the contribution degree may be calculated based on the following arithmetic expression. The information processing apparatus 1 can normalize the regression coefficient with respect to the item Ai (i=1, 2, . . . , N) of the input data, for example, such that the sum of the absolute values of the normalized regression coefficients becomes 100, and set a value obtained by converting the regression coefficient into a ratio (%) as the contribution degree.

$$Contribution Degree of Item Ai [ \% ] = \qquad [ Equation 1 ]$$

$$\frac{\vert Normalized Regression Coefficients of Item Ai \vert}{{\sum }_{i = 0}^{N} \vert Normalized Regression Coefficients of Item Ai \vert} \times 100$$

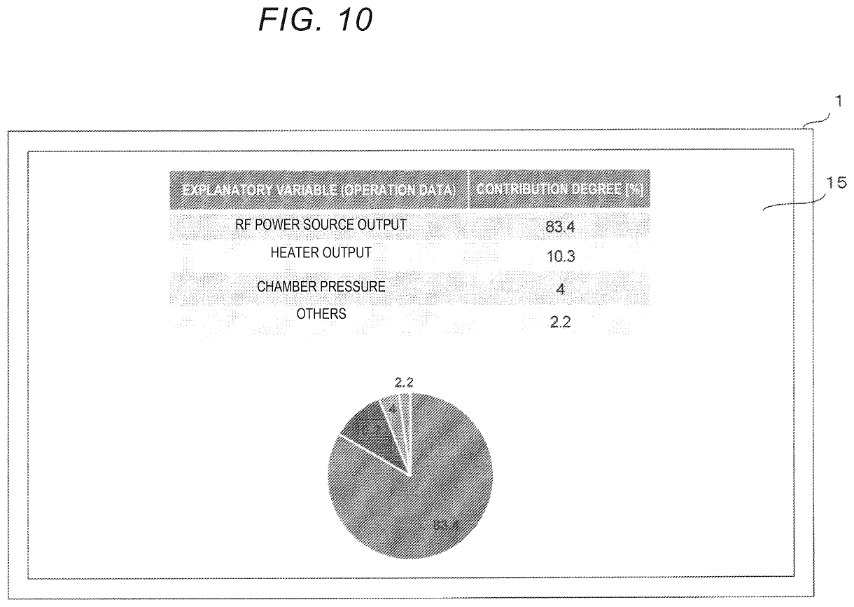

FIG. 10 is a schematic diagram showing an example of information display relating to the contribution degree. For example, this drawing is an example of information displayed in Step S25 of the flowchart in FIG. 9. In the information display example shown in FIG. 10, the information processing apparatus 1 displays a table showing the contribution degree of each item included in the operation data, and a pie chart showing a ratio of the contribution degree with regard to a plurality of items included in the operation data in such a manner that the table and the pie chart are aligned up and down on the screen of the display unit 15. In the table showing the contribution degree of each item, for example, the plurality of items included in the operation data are aligned from top to bottom in descending order of the contribution degree, and the ratio [%] of the contribution degree of each item to all contribution degrees is shown in association with each item. In the present example, top three items having highest contribution degree in the plurality of items included in the operation data are shown, and with respect to the other items, a total value of the contribution degree is shown as “others”. The pie chart is a graph in which the plurality of items included in the operation data are associated with an area of a sector obtained by performing color-coding on the ratio of the contribution degrees of the plurality of items to all contribution degrees, based on the contribution degrees shown in the table described above.

Since the information processing apparatus 1 calculates and displays the contribution degrees of the plurality of items included in the operation data, the user can determine which item is effective to be improved, for example, when the power consumption is large. Processes such as calculation and display of the contribution degrees of the plurality of items included in the operation data may be performed by another information processing apparatus different from the information processing apparatus 1 that performs monitoring, control, and the like on the semiconductor manufacturing apparatus 2.

### (3) Automatic Stop of Unit in Standby State

The information processing apparatus 1B according to the present embodiment acquires the operation data when the semiconductor manufacturing apparatus 2B performs the semiconductor manufacturing process and acquires the prediction value of the sensor data by using the prediction model 5 based on the acquired operation data. For example, the information processing apparatus 1B acquires the prediction value of the power consumption of each unit by the prediction model 5 and determines that the unit is in a standby state when the prediction value of the power consumption of each unit is smaller than a threshold value. The information processing apparatus 1B can reduce the power consumption by stopping the operation of the unit in the standby state and stopping the power supply to the unit.

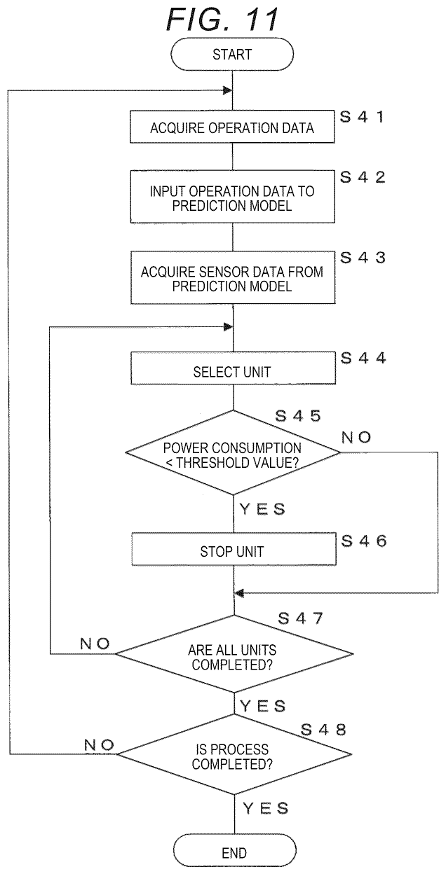

FIG. 11 is a flowchart showing an example of a procedure of a unit stopping process performed by the information processing apparatus 1B according to the present embodiment. The processor 11 of the information processing apparatus 1B according to the present embodiment acquires the operation data output by the semiconductor manufacturing apparatus 2B when the semiconductor manufacturing apparatus 2B performs the semiconductor manufacturing process (Step S41). The processor 11 inputs the operation data acquired in Step S41 to the trained prediction model 5 in which information such as a structure and parameters is stored in the prediction model storage unit 12c (Step S42). The processor 11 acquires the sensor data output by the prediction model 5 with respect to the operation data input in Step S42 (Step S43).

The processor 11 selects one unit serving as a processing target from the plurality of units provided in the semiconductor manufacturing apparatus 2B (Step S44). From the sensor data acquired in Step S43, the processor 11 acquires the prediction value of the power consumption relating to the unit selected in Step S44 and determines whether the power consumption is smaller than the predetermined threshold value (Step S45). For example, the threshold value is a value determined in advance by the user such as a designer or an administrator of the information processing system according to the present embodiment, and different threshold values may be adopted for each unit. When the power consumption is smaller than the threshold value (Step S45: YES), the processor 11 stops the operation of the target unit (Step S46) and advances the process to Step S47. When the power consumption is equal to or greater than the threshold value (S45: NO), the processor 11 advances the process to Step S47.

The processor 11 determines whether the power consumption is completely determined for all of the units provided in the semiconductor manufacturing apparatus 2B (Step S47). When the power consumption is not completely determined for all of the units (NO in Step S47), the processor 11 returns the process to Step S44, selects another unit, and repeats the above-described process. When the power consumption is completely determined for all of the units (Step S47: YES), the processor 11 determines whether the semiconductor manufacturing process of the semiconductor manufacturing apparatus 2B is completed (Step S48). When the semiconductor manufacturing process is not completed (S48: NO), the processor 11 returns the process to Step S41, acquires new operation data from the semiconductor manufacturing apparatus 2B, and repeats the above-described process. When the semiconductor manufacturing process is completed (S48: YES), the processor 11 completes the process.

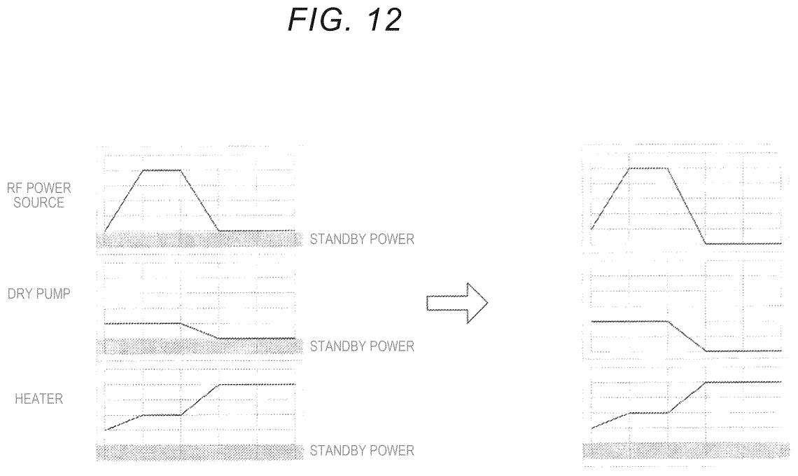

FIG. 12 is a schematic diagram for describing an advantageous effect of the automatic stop of the unit in the standby state. In this drawing, each graph shows a change in the power consumption with regard to three units including an RF power source, a dry pump, and a heater in the plurality of units provided in the semiconductor manufacturing apparatus 2B. Each graph is a polygonal line graph in which the horizontal axis represents a time, and the vertical axis represents the power consumption of the unit. The graph when the automatic stop of the unit in the standby state is not performed is shown on a left side in FIG. 12, and the graph when the automatic stop of the unit in the standby state is performed is shown on a right side.

When the automatic stop is not performed, as shown in the graph on the left side in FIG. 12, each unit continues to consume standby power (region indicated by a light gray color in this drawing), even in the standby state where each unit does not substantially perform the process. For example, a value obtained by providing a margin for the standby power is set in advance as a threshold value, and the information processing apparatus 1B determines whether each unit is in the standby state based on the threshold value, and automatically stops the operation of the unit whose power consumption exceeds the threshold value. In the present embodiment, the automatic stop of the unit by the information processing apparatus 1B switches the state of the unit to a state where the standby power is not consumed, for example, by cutting off the power supply to the unit. Accordingly, as shown in the graph on the right side in FIG. 12, the information processing apparatus 1B performs the automatic stop on the RF power source and the dry pump which are determined to be in the standby state, and the power consumption of the units is reduced to a value smaller than a standby power amount, for example, 0.

In the present example, a case has been described where the information processing apparatus 1B that performs monitoring, controlling, or the like on the semiconductor manufacturing apparatus 2B having no sensor 3 performs the automatic stop of the unit by using the prediction model 5. Meanwhile, the information processing apparatus 1A that performs monitoring, controlling, or the like on the semiconductor manufacturing apparatus 2A provided with the sensors 3 may perform the same process. However, the information processing apparatus 1A may perform the same automatic stop by using the sensor data output by the sensor 3 without using the prediction model 5.

### (4) Verification of Process Timing

In the information processing system according to the present embodiment, the user can verify a process timing of the plurality of units provided in the semiconductor manufacturing apparatus 2, based on the sensor data output by the prediction model 5. From the operation data acquired when the semiconductor manufacturing apparatus 2B performs the semiconductor manufacturing process and stored in the process DB 12b, for example, the information processing apparatus 1B reads the operation data from the start to the end of the semiconductor manufacturing process with respect to one wafer. The information processing apparatus 1B inputs the operation data read from the process DB 12b to the prediction model 5 and acquires the sensor data output by the prediction model 5.

The semiconductor manufacturing apparatus 2B is configured to include the plurality of units, and for example, the sensor data includes the prediction values such as the power consumption, the drainage amount, and the gas exhaust amount for each of the units. With regard to the drainage amount or the gas exhaust amount, the value may be included in the sensor data for only the unit that performs the drainage or the gas exhaust. With regard to the power consumption, it is preferable that the value is included in the sensor data for all of the units that consume the power. From the sensor data output by the prediction model 5, the information processing apparatus 1B prepares a graph showing a time-dependent change in the power consumption, the drainage amount, or the gas exhaust amount of each unit, and displays a plurality of the graphs prepared for the plurality of units on the display unit 15 in such a manner that the plurality of graphs are aligned.

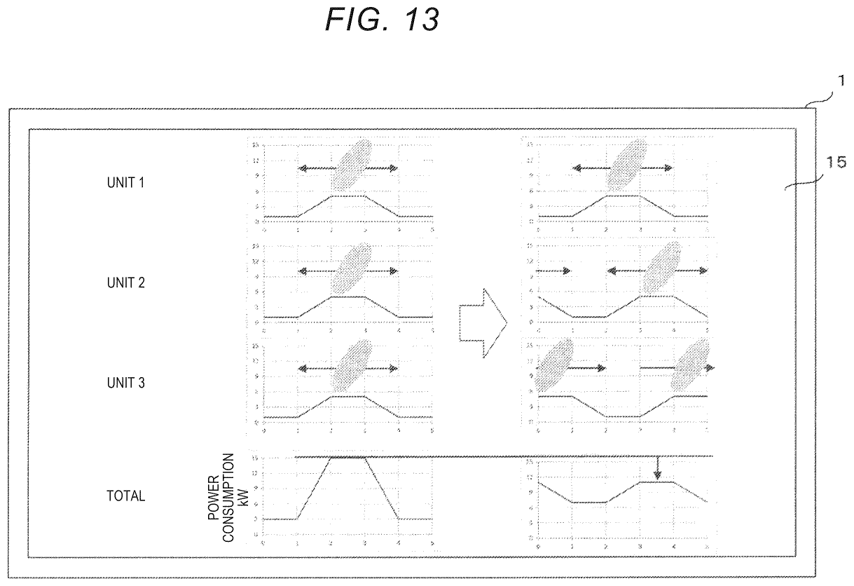

FIG. 13 is a schematic diagram showing a display example according to the process timing verification. In the shown display example, the information processing apparatus 1B prepares each graph showing a time-dependent change in the power consumption of the three units 1 to 3 provided in the semiconductor manufacturing apparatus 2B and displays the three graphs in such a manner that the three graphs are aligned in an up-down direction. The information processing apparatus 1B displays a graph of the total power consumption of the three units 1 to 3 below the three graphs. Each graph of the units 1 to 3 and the graph of the total power consumption are graphs in each of which the horizontal axis represents a time and the vertical axis represents the power consumption, and it is preferable that scales of the vertical axis and the horizontal axis of the four graphs are the same as each other.

The information processing apparatus 1B sets the graph based on the sensor data output by the prediction model 5 as a graph of current power consumption. For example, the information processing apparatus 1B prepares the graph of the power consumption when a process timing of each unit is changed and displays the graph of the current power consumption and the graph of the power consumption after the timing is changed, in such a manner that the graphs are aligned to the right and left sides of the display unit 15. In the shown display example, from the four graphs displayed on the left side of the display unit 15, the three units 1 to 3 currently perform the process at the same timing. Since peak timings at which the power is consumed overlap each other, a maximum value of the total power consumption reaches approximately 15 kW. In contrast, in the four graphs displayed on the right side of the display unit 15, timings at which the three units 1 to 3 perform the process are different from each other, and the maximum value of the total power consumption is suppressed to 12 kW or smaller.

For example, the information processing apparatus 1B receives an input of information relating to how much the processing of each unit is to be changed with respect to the graph of the current power consumption from the user, and prepares a graph after the timing change by moving the graph of the current power consumption of each of the units 1 to 3 in a time axis direction in accordance with the received information. The information processing apparatus 1B prepares graphs of total power consumption, based on the graph obtained by changing a process timing of each of the units 1 to 3, and aligns and displays the graphs on the display unit 15. Instead of receiving the input from the user, for example, the information processing apparatus 1B may search for the process timing at which the maximum value of the total power consumption is smallest and may prepare and display the graph at this timing. The graph after the timing change may be prepared, for example, by using the simulator 7 shown in FIG. 8, instead of being prepared by moving the current graph in the time axis direction.

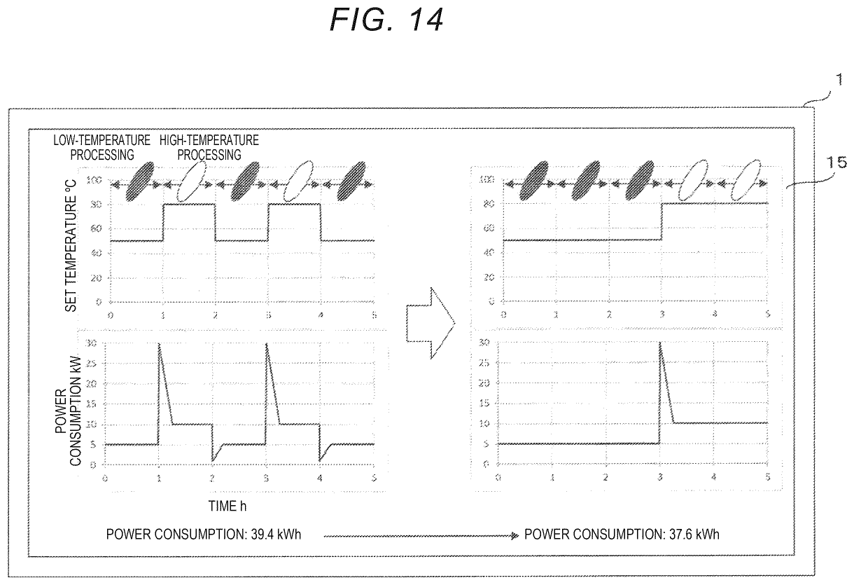

FIG. 14 is a schematic diagram showing a display example according to the process timing verification. In the display example in FIG. 14, the information processing apparatus 1B displays a graph showing a time-dependent change in a set temperature of the semiconductor manufacturing process and a graph showing a time-dependent change in the power consumption of the semiconductor manufacturing apparatus 2B in such a manner that the graphs are aligned up and down. The information processing apparatus 1B extracts information on the set temperature from the recipe data included in the operation data acquired from the semiconductor manufacturing apparatus 2B and prepares the graph showing the time-dependent change in the set temperature based on the extracted information. The information processing apparatus 1B inputs the operation data to the prediction model 5, acquires the sensor data output by the prediction model 5, extracts the information on the power consumption included in the acquired sensor data, and prepares the graph showing the time-dependent change in the power consumption of the semiconductor manufacturing apparatus 2B based on the extracted information.

For example, the information processing apparatus 1 prepares the graph of the set temperature and the power consumption when the timing for changing the set temperature of the semiconductor manufacturing apparatus 2B is changed with respect to the graph of the current set temperature and the power consumption, and displays the current graph and the graph after the timing change in such a manner that the graphs are aligned to the right and left sides of the display unit 15. From the graph displayed on the left side in the shown example, in the current state, low-temperature processing and high-temperature processing are alternately switched and performed with regard to the set temperature, and the power consumption increases when the low-temperature processing is switched to the high-temperature processing. In contrast, in the graph displayed on the right side, the timing for changing the temperature settings is changed such that the low-temperature processing is first consecutively performed, thereafter, the low-temperature processing is switched to the high-temperature processing, and the high-temperature processing is consecutively performed. Since the timing is changed in this way, the number of switching times from the low-temperature processing to the high-temperature processing is reduced, and the number of increasing times of the power consumption is reduced. Therefore, the power consumption amount can be reduced as a whole.

For example, the information processing apparatus 1B receives an input of a change pattern of a new set temperature from the user with respect to a change pattern of the current set temperature, and performs a simulation for example, by using the simulator 7 in accordance with the received details. The information processing apparatus 1B acquires the operation data output by the simulator 7 as a simulation result, inputs the acquired operation data to the prediction model 5, acquires the sensor data, and generates the graph of the power consumption.

The process relating to the verification of the process timings may be performed by another apparatus different from the information processing apparatus 1 that performs monitoring, control, or the like on the semiconductor manufacturing apparatus 2. For example, it is preferable that the process is performed by an information processing apparatus in which the simulator 7 is operated.

### SUMMARY

In the information processing system according to the present embodiment having the configuration described above, when the semiconductor manufacturing apparatus 2A provided with the plurality of sensors 3 is operated, the information processing apparatus 1A acquires the operation data of the semiconductor manufacturing apparatus 2A and the sensor data output by the sensor 3, and based on the acquired operation data and sensor data, the prediction model 5 for outputting the prediction value of the sensor data is generated by using the machine learning in response to an input of the operation data. The information processing apparatus 1A transmits the generated prediction model 5 to the information processing apparatus 1B that performs monitoring, controlling, or the like on the semiconductor manufacturing apparatus 2B having no sensor 3, thereby disposing the prediction model 5 for the semiconductor manufacturing apparatus 2A. Accordingly, in the information processing system according to the present embodiment, for example, when the semiconductor manufacturing apparatus 2B provided with the sensors 3 is operated, the prediction value of the sensor data based on the operation data can be acquired and used for various controls, verifications, or the like.

In the information processing system according to the present embodiment, the information processing apparatus 1B acquires the operation data of the semiconductor manufacturing apparatus 2B, inputs the acquired operation data to the prediction model 5 subjected to the machine learning to output the sensor data in response to an input of the operation data, acquires the sensor data output by the prediction model 5, and outputs the information relating to the sensor data. Accordingly, the information processing apparatus 1B can predict the sensor data by using the prediction model 5 generated in advance based on the operation data acquired from the semiconductor manufacturing apparatus 2B having no sensor 3, and can perform monitoring, control, and the like on the semiconductor manufacturing apparatus 2B.

In the information processing system according to the present embodiment, it is preferable that the plurality of sensors 3 include the sensor for measuring the power consumption, the sensor for measuring the drainage amount, or the sensor for measuring the gas exhaust amount. It is preferable that the operation data include the process log data output by the semiconductor manufacturing apparatus 2, the recipe data set in the semiconductor manufacturing apparatus 2, the wafer transfer history data of the semiconductor manufacturing apparatus 2, the error data output by the semiconductor manufacturing apparatus 2, or the like. Accordingly, the prediction model 5 that predicts the power consumption amount, the drainage amount, the gas exhaust amount, or the like of the semiconductor manufacturing apparatus 2 can be generated, based on the data acquired from the semiconductor manufacturing apparatus 2A and the sensor 3, and the power consumption amount, the drainage amount, the gas exhaust amount, or the like of the semiconductor manufacturing apparatus 2B having no sensor 3 can be predicted by using the prediction model 5 generated in advance.

In the information processing system according to the present embodiment, the information processing apparatus 1B calculates the contribution degree of each item of the operation data to the sensor data output by the prediction model 5 and outputs information relating to the calculated contribution degree. Accordingly, the user can recognize which item in the plurality of items included in the operation data has a high contribution degree to the sensor data and review the recipe of the semiconductor manufacturing process, for example.

In the information processing system according to the present embodiment, the information processing apparatus 1B determines standby states of the plurality of units provided in the semiconductor manufacturing apparatus 2B based on the sensor data output by the prediction model 5, and stops the operation of the unit in the standby state. Accordingly, it can be expected that the power consumption of the semiconductor manufacturing apparatus 2B is further reduced.

In the information processing system according to the present embodiment, information relating to the time-dependent change in the power consumption of the plurality of units provided in the semiconductor manufacturing apparatus 2B is output based on the sensor data output by the prediction model 5. Accordingly, for example, the user can expect further reducing a peak of the power consumption of the semiconductor manufacturing apparatus 2B by recognizing the peak of the power consumption of each unit and setting the semiconductor manufacturing process of the semiconductor manufacturing apparatus 2B to avoid a possibility that the peaks of the power consumption of the plurality of units temporally overlap each other.

In the present embodiment, the information processing apparatus 1A is configured to transmit the generated prediction model 5 to the information processing apparatus 1B via the network N. Meanwhile, the present disclosure is not limited thereto, and for example, the prediction model 5 may be exchanged between the information processing apparatus 1A and the information processing apparatus 1B via a recording medium such as a memory card or an optical disc, or the prediction model 5 may be exchanged by using any other method. Instead of generating the prediction model 5 by the information processing apparatus 1A that performs monitoring, controlling, or the like on the semiconductor manufacturing apparatus 2A, for example, another information processing apparatus such as a server device different from the information processing apparatuses 1A and 1B may acquire the operation data and the sensor data from the information processing apparatus 1A to generate the prediction model 5, and the information processing apparatus such as the server device may transmit the prediction model 5 to the information processing apparatus 1B.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims). For example, the present disclosure includes the following embodiments.

### (Appendix 1)

An information processing method includes acquiring operation data of a first semiconductor manufacturing apparatus provided with a plurality of sensors and sensor data output by the sensors, when the first semiconductor manufacturing apparatus is operated, using machine learning to generate a learning model for outputting the sensor data in response to an input of the operation data, based on the acquired operation data and the acquired sensor data, and disposing the generated learning model in a second semiconductor manufacturing apparatus different from the first semiconductor manufacturing apparatus.

### (Appendix 2)

In the information processing method according to Appendix 1, the plurality of sensors may include a sensor for measuring power consumption, a sensor for measuring a drainage amount, or a sensor for measuring a gas exhaust amount.

### (Appendix 3)

In the information processing method according to Appendix 1 or 2, the operation data may include process log data output by the first semiconductor manufacturing apparatus, process recipe data set in the first semiconductor manufacturing apparatus, wafer transfer history data of the first semiconductor manufacturing apparatus, or error data output by the first semiconductor manufacturing apparatus.

### (Appendix 4)

In the information processing method according to any one of Appendices 1 to 3, the number of the sensors provided in the second semiconductor manufacturing apparatus may be smaller than the number of the sensors provided in the first semiconductor manufacturing apparatus.

### (Appendix 5)

In the information processing method according to any one of Appendices 1 to 4, the learning model may output power consumption, a drainage amount, or a gas exhaust amount of a semiconductor manufacturing apparatus when process log data output by the semiconductor manufacturing apparatus is input.

### (Appendix 6)

In the information processing method according to any one of Appendices 1 to 5, a plurality of sensors for measuring sensor data relating to an environment including a sensor for measuring power consumption, a sensor for measuring a drainage amount, and a sensor for measuring a gas exhaust amount may be provided as many as a predetermined number in the first semiconductor manufacturing apparatus to be operated on a test basis, when the second semiconductor manufacturing apparatus is newly installed at one or more bases, the generated learning model may be disposed in the second semiconductor manufacturing apparatus by providing a smaller number of the sensors than the predetermined number or without providing the sensors in the second semiconductor manufacturing apparatus, and the operation data acquired in conjunction with an initial operation of the second semiconductor manufacturing apparatus may be input to the learning model, and the sensor data may be acquired without using the sensor.

### (Appendix 7)

A computer program causing a computer to execute a process including acquiring operation data of a first semiconductor manufacturing apparatus provided with a plurality of sensors and sensor data output by the sensors, when the first semiconductor manufacturing apparatus is operated, using machine learning to generate a learning model for outputting the sensor data in response to an input of the operation data, based on the acquired operation data and the acquired sensor data, and outputting information relating to the generated learning model as information for disposing in a second semiconductor manufacturing apparatus different from the first semiconductor manufacturing apparatus.

### (Appendix 8)

A computer program causing a computer to execute a process including acquiring operation data of a second semiconductor manufacturing apparatus, acquiring sensor data output by a learning model by inputting the acquired operation data to the learning model subjected to machine learning to output the sensor data in response to an input of the operation data, and outputting the acquired sensor data.

### (Appendix 9)

In the computer program according to Appendix 7 or 8, the learning model may be generated by using the machine learning to output the sensor data in response to an input of the operation data, based on the acquired operation data of the first semiconductor manufacturing apparatus provided with the plurality of sensors and the sensor data output by the sensors when the first semiconductor manufacturing apparatus is operated.

### (Appendix 10)

In the computer program according to any one of Appendices 7 to 9, the plurality of sensors may include a sensor for measuring power consumption, a sensor for measuring a drainage amount, or a sensor for measuring a gas exhaust amount.

### (Appendix 11)

In the computer program according to any one of Appendices 7 to 10, the operation data may include process log data output by the first semiconductor manufacturing apparatus, process recipe data set in the first semiconductor manufacturing apparatus, wafer transfer history data of the first semiconductor manufacturing apparatus, or error data output by the first semiconductor manufacturing apparatus.

### (Appendix 12)

In the computer program according to any one of Appendices 7 to 11, the learning model may output power consumption, a drainage amount, or a gas exhaust amount of the semiconductor manufacturing apparatus when process log data output by the semiconductor manufacturing apparatus is input.

### (Appendix 13)

In the computer program according to any one of Appendices 7 to 12, the operation data may include a plurality of items, a contribution degree of each of the items of the operation data to the sensor data output by the learning model may be calculated, and the calculated contribution degree may be output.

### (Appendix 14)

In the computer program according to any one of Appendices 7 to 13, a standby state of a plurality of units provided in the second semiconductor manufacturing apparatus may be determined, based on the sensor data output by the learning model, and an operation of the unit in the standby state may be stopped.

### (Appendix 15)

In the computer program according to any one of Appendices 7 to 14, the sensor data may include power consumption data of each unit with regard to a plurality of units provided in the second semiconductor manufacturing apparatus, and a time-dependent change in power consumption of the plurality of units may be output, based on the sensor data output by the learning model.

### (Appendix 16)

An information processing apparatus includes an acquisition unit that acquires operation data of a first semiconductor manufacturing apparatus provided with a plurality of sensors and sensor data output by the sensors, when the first semiconductor manufacturing apparatus is operated, a generator that uses machine learning to generate a learning model for outputting the sensor data in response to an input of the operation data, based on the acquired operation data and the acquired sensor data, and an output unit that outputs information relating to the generated learning model as information for disposing in a second semiconductor manufacturing apparatus different from the first semiconductor manufacturing apparatus.

### (Appendix 17)

An information processing apparatus includes a first acquisition unit that acquires operation data of a second semiconductor manufacturing apparatus, a second acquisition unit that acquires sensor data output by a learning model by inputting the acquired operation data to the learning model subjected to machine learning to output the sensor data in response to an input of the operation data, and an output unit that outputs the acquired sensor data.

1. An information processing method comprising:
acquiring operation data of a first semiconductor manufacturing apparatus provided with a plurality of sensors and sensor data output by the sensors when the first semiconductor manufacturing apparatus is operated;
using machine learning to generate a learning model for outputting the sensor data in response to an input of the operation data based on the acquired operation data and the acquired sensor data; and
disposing the generated learning model in a second semiconductor manufacturing apparatus different from the first semiconductor manufacturing apparatus.

2. The information processing method according to claim 1, wherein the plurality of sensors include a sensor for measuring power consumption, a sensor for measuring a drainage amount, or a sensor for measuring a gas exhaust amount.

3. The information processing method according to claim 1, wherein the operation data includes process log data output by the first semiconductor manufacturing apparatus, process recipe data set in the first semiconductor manufacturing apparatus, wafer transfer history data of the first semiconductor manufacturing apparatus, or error data output by the first semiconductor manufacturing apparatus.

4. The information processing method according to claim 1, wherein a number of the sensors provided in the second semiconductor manufacturing apparatus is smaller than a number of the sensors provided in the first semiconductor manufacturing apparatus.

5. The information processing method according to claim 1, wherein the learning model outputs power consumption, a drainage amount, or a gas exhaust amount of a semiconductor manufacturing apparatus when process log data output by the semiconductor manufacturing apparatus is input.

6. The information processing method according to claim 1, wherein
a predetermined number of a plurality of sensors for measuring sensor data relating to an environment including a sensor for measuring power consumption, a sensor for measuring a drainage amount, and a sensor for measuring a gas exhaust amount are provided in the first semiconductor manufacturing apparatus to be operated on a test basis,
when the second semiconductor manufacturing apparatus is newly installed at one or more bases, the generated learning model is disposed in the second semiconductor manufacturing apparatus having a smaller number of sensors than the predetermined number or having no sensors, and
the operation data acquired in conjunction with an initial operation of the second semiconductor manufacturing apparatus is input to the learning model and sensor data is acquired without using a sensor.

7. A non-transitory computer readable medium storing a computer program including instructions which cause a computer to execute a process comprising:
acquiring operation data of a first semiconductor manufacturing apparatus provided with a plurality of sensors and sensor data output by the sensors when the first semiconductor manufacturing apparatus is operated;
using machine learning to generate a learning model for outputting the sensor data in response to an input of the operation data based on the acquired operation data and the acquired sensor data; and
outputting information relating to the generated learning model as information for disposing the generated learning model in a second semiconductor manufacturing apparatus different from the first semiconductor manufacturing apparatus.

8. A non-transitory computer readable medium storing a computer program including instructions which cause a computer to execute a process comprising:
acquiring operation data of a second semiconductor manufacturing apparatus;
acquiring sensor data output by a learning model by inputting the acquired operation data to the learning model subjected to machine learning to output the sensor data in response to an input of the operation data; and
outputting the acquired sensor data.

9. The non-transitory computer readable medium according to claim 7, wherein the learning model is generated based on the acquired operation data of the first semiconductor manufacturing apparatus provided with the plurality of sensors and the sensor data output by the sensors when the first semiconductor manufacturing apparatus is operated.

10. The non-transitory computer readable medium according to claim 9, wherein the plurality of sensors include a sensor for measuring power consumption, a sensor for measuring a drainage amount, or a sensor for measuring a gas exhaust amount.

11. The non-transitory computer readable medium according to claim 9, wherein the operation data includes process log data output by the first semiconductor manufacturing apparatus, process recipe data set in the first semiconductor manufacturing apparatus, wafer transfer history data of the first semiconductor manufacturing apparatus, or error data output by the first semiconductor manufacturing apparatus.

12. The non-transitory computer readable medium according to claim 8, wherein the learning model outputs power consumption, a drainage amount, or a gas exhaust amount of the semiconductor manufacturing apparatus when process log data output by the semiconductor manufacturing apparatus is input.

13. The non-transitory computer readable medium according to claim 8, wherein
the operation data includes a plurality of items,
a contribution degree of each of the items of the operation data to the sensor data output by the learning model is calculated, and
the calculated contribution degree is output.

14. The non-transitory computer readable medium according to claim 8, wherein
a standby state of a plurality of units provided in the second semiconductor manufacturing apparatus is determined based on the sensor data output by the learning model, and
an operation of at least one of the units in the standby state is stopped.

15. The computer program according to claim 8, wherein
the sensor data includes power consumption data of each unit with regard to a plurality of units provided in the second semiconductor manufacturing apparatus, and
a time-dependent change in power consumption of the plurality of units is output based on the sensor data output by the learning model.

16. An information processing apparatus comprising:
a processor programmed to:
acquire operation data of a first semiconductor manufacturing apparatus provided with a plurality of sensors and sensor data output by the sensors when the first semiconductor manufacturing apparatus is operated;
use machine learning to generate a learning model for outputting the sensor data in response to an input of the operation data based on the acquired operation data and the acquired sensor data; and
output information relating to the generated learning model as information for disposing the generated learning model in a second semiconductor manufacturing apparatus different from the first semiconductor manufacturing apparatus.

17. The information processing apparatus according to claim 16, wherein the second semiconductor manufacturing apparatus is controlled based upon an output of the generated learning model.

18. An information processing apparatus comprising:
a processor programmed to:
acquire operation data of a second semiconductor manufacturing apparatus;
acquire sensor data output by a learning model by inputting the acquired operation data to the learning model subjected to machine learning to output the sensor data in response to an input of the operation data; and
output the acquired sensor data.

19. The information processing apparatus according to claim 18, wherein the processor is programmed to control the second semiconductor manufacturing apparatus based upon the acquired sensor data output by the learning model.
